(19) United States
(12) Patent Application Publication
(10) Pub. No.: US 2022/0302104 A1
(43) Pub. Date: Sep. 22, 2022

(54) BIDIRECTIONAL ESD PROTECTION DEVICE AND ELECTRONIC APPARATUS

(71) Applicant: CSMC TECHNOLOGIES FAB2 CO., LTD., Wuxi (CN)

(72) Inventors: Danye LIANG, Wuxi (CN); Guangyang WANG, Wuxi (CN)

(21) Appl. No.: 17/639,076

(22) PCT Filed: Aug. 6, 2020
(86) PCT No.: PCT/CN2020/107324

§ 371 Date: Feb. 28, 2022

(30) Foreign Application Priority Data
Sep. 26, 2019 (CN) 201910916709.9

(51) Int. Cl. H01L 27/02

(52) U.S. Cl. CPC H01L 27/0262; H01L 27/0296

(57) ABSTRACT

In one aspect, a bidirectional Electro-Static Discharge (ESD) protection device includes: a first well region, a second well region and a third well region formed in a semiconductor substrate; two or more first injection regions and two or more second injection regions formed in the first well region, and two or more fourth injection regions and two or more fifth injection regions formed in the second well region; and third injection regions formed at a junction of the first well region and the third well region and at a junction of the second well region and the third well region.

### CROSS-REFERENCES TO RELATED APPLICATIONS

This application claims priority to Chinese Patent Application No. 2019109167099, entitled “BIDIRECTIONAL ESD PROTECTION DEVICE AND ELECTRONIC APPARATUS” and filed with the Chinese Patent Office on Sep. 26, 2019, the entire contents of which are incorporated herein by reference.

### TECHNICAL FIELD

The present disclosure relates to the field of semiconductor technologies, and in particular, to a bidirectional Electro-Static Discharge (ESD) protection device and an electronic apparatus.

### BACKGROUND

The statements herein provide only background information relevant to the present disclosure and do not necessarily constitute exemplary technologies.

With the continuous scaling down of CMOS technologies, IC chip failure caused by ESD has become a major reliability problem. In particular, small devices with an ultra-thin gate oxide layer and a thin dielectric layer show a more serious trend of ESD damage. ESD protection designs are becoming increasingly challenging and difficult in nanoscale CMOS technologies. There are four common ESD discharge modes, which are as follows. 1. PS mode: A positive ESD pulse appears in an 10 port (such as an input terminal), and the IO port discharges to the ground. 2. NS mode: A negative ESD pulse appears in the IO port, and the ground discharges to the IO port. 3. ND mode: The negative ESD pulse appears in the IO port, a VDD discharge to the IO port. 4. PD mode: The positive ESD pulse appears in the IO port, and the IO port discharges the VDD. ESD current directions of the above discharge modes are shown in FIG. 1. As can be seen from FIG. 1, in order to meet requirements of complete ESD protection design, at least four devices that can provide unidirectional protection are required; while at least two devices that can provide bidirectional protection are required.

A Silicon Controlled Rectifier (SCR), as a common ESD protection device, is widely used in various ESD protection designs. However, traditional ESD devices can provide unidirectional protection only, and a large number of devices are required to design a complete protection scheme, which occupies an excessive layout area. Therefore, new devices that can provide multidirectional protection are attracting more and more attention. It is a development direction to improve an SCR structure so that it can provide bidirectional protection. However, the traditional bidirectional structure is triggered by breakdown of p-well and N-well junctions, resulting in an excessively high trigger voltage. After the triggering, a latch-up structure in an SCR path enters deep positive feedback, resulting in an excessively low sustaining voltage. As a result, an ESD design window is excessively large and is required to be adjusted for protection.

Therefore, there is a need to improve a bidirectional ESD protection device formed by the SCR, so that it has a relatively high sustaining voltage, and greatly improved ESD robustness compared with the previous structure.

### SUMMARY

According to various embodiments of the present disclosure, a bidirectional ESD protection device and an electronic apparatus are provided.

A bidirectional ESD protection device, the bidirectional ESD protection device including a bidirectional SCR device formed on a semiconductor substrate, the bidirectional ESD protection device including: a first well region and a second well region having a first conductivity type and formed in a semiconductor substrate;

a third well region having a second conductivity type and formed in the semiconductor substrate, the third well region being located between the first well region and the second well region and located on a same straight line with the first well region and the second well region, the second conductivity type being opposite to the first conductivity type;

two or more first injection regions and two or more second injection regions formed in the first well region, and two or more fourth injection regions and two or more fifth injection regions formed in the second well region, the first injection regions and the fourth injection regions having the first conductivity type, the second injection regions and the fifth injection regions having the second conductivity type, the first injection regions being spaced along a length direction of the first well region, the second injection regions being spaced along the length direction of the first well region, the fourth injection regions being spaced along a length direction of the second well region, the fifth injection regions being spaced along the length direction of the second well region, the first injection regions and the second injection regions in the length direction of the first well region and the fourth injection regions and the fifth injection regions in the length direction of the second well region being respectively located on different straight lines and staggered from each other by a distance; and

third injection regions formed at a boundary of the first well region and the third well region and at a boundary of the second well region and the third well region, the third injection regions having the first conductivity type, the third injection regions extending along the length direction of the first well region;

wherein the first injection regions, the second injection regions, the third injection regions, the fourth injection regions, and the fifth injection regions constitute the bidirectional SCR device with the first well region, the second well region and the third well region, the first injection regions and the second injection regions in the first well region are used as a first electrode of the bidirectional SCR device, the fourth injection regions and the fifth injection regions in the second well region are used as a second electrode of the bidirectional SCR device, and the first electrode and the second electrode are an anode and a cathode of the bidirectional SCR device respectively.

An electronic apparatus, including the bidirectional ESD protection device as described above and electronic components connected to the bidirectional ESD protection device.

Details of one or more embodiments of the present disclosure are set forth in the following accompanying drawings and descriptions. Other features, objectives, and advantages of the present disclosure will become obvious with reference to the specification, the accompanying drawings, and the claims.

### BRIEF DESCRIPTION OF THE DRAWINGS

In order to more clearly illustrate the technical solutions in embodiments of the present disclosure or exemplary technologies, the accompanying drawings used in the description of the embodiments or exemplary technologies will be briefly introduced below. It is apparent that, the accompanying drawings in the following description are only some embodiments of the present disclosure, and other drawings can be obtained by those of ordinary skill in the art from the provided drawings without creative efforts.

FIG. 1 is a schematic diagram of a discharge current of an ESD protection device;

FIG. 2A is a schematic sectional view and an equivalent circuit diagram of a unidirectional SCR device in a conventional art;

FIG. 2B is a schematic sectional view and an equivalent circuit diagram of a first bidirectional SCR device in the conventional art;

FIG. 3A is a schematic sectional view and an equivalent circuit diagram of a second bidirectional SCR device in the conventional art;

FIG. 3B is a schematic top view of the bidirectional SCR device shown in FIG. 3A.

FIG. 4A is a schematic sectional view and an equivalent circuit diagram of a third bidirectional SCR device in the conventional art;

FIG. 4B is a schematic top view of the bidirectional SCR device shown in FIG. 4A.

FIG. 5A is a schematic sectional view and an equivalent circuit diagram of a fourth bidirectional SCR device in the conventional art;

FIG. 5B is a schematic top view of the bidirectional SCR device shown in FIG. 5A.

FIG. 6A is a schematic top view of a bidirectional ESD protection device according to an embodiment of the present disclosure;

FIG. 6B is a schematic sectional view and an equivalent circuit diagram of the bidirectional ESD protection device shown in FIG. 6A;

FIG. 6C is a schematic top view of the bidirectional ESD protection device according to another embodiment of the present disclosure;

FIG. 7 is a diagram of transmission line pulse (TLP) test results of the bidirectional ESD protection devices shown in FIG. 5A, FIG. 6A and FIG. 6C: and

FIG. 8 is a schematic diagram of an electronic apparatus according to an embodiment of the present disclosure.

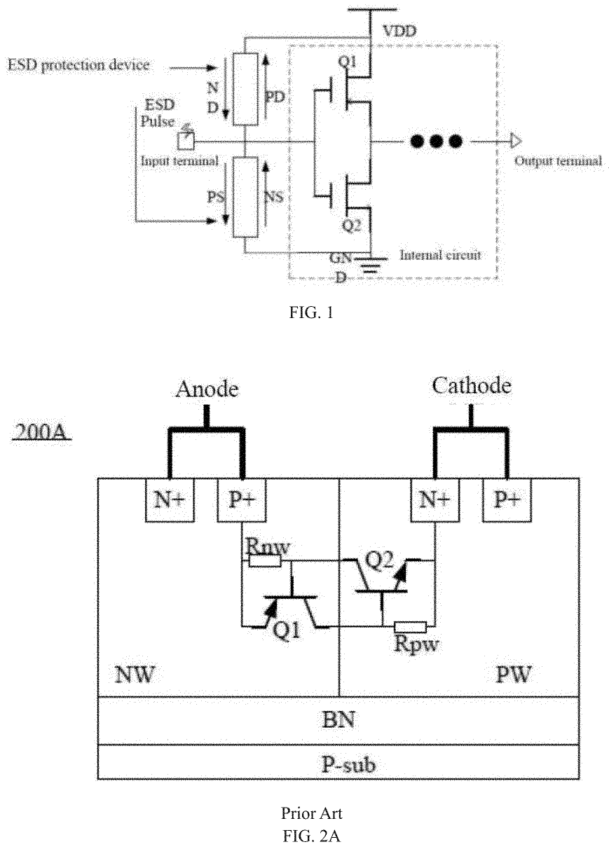

### DETAILED DESCRIPTION OF THE EMBODIMENTS

In the following descriptions, a lot of specific details are provided to give a more thorough understanding of the present disclosure. However, it is obvious for those skilled in the art that the present disclosure can be implemented without one or more of the details. In other examples, some technical features well known in the art are not described to avoid confusion with the present disclosure.

In order to understand the present disclosure thoroughly, detailed structures and steps are presented in the following descriptions to explain the technical solutions proposed in the present disclosure. Preferred embodiments of the present disclosure are described in detail below. However, the present disclosure may be implemented in other manners in addition to the detailed descriptions.

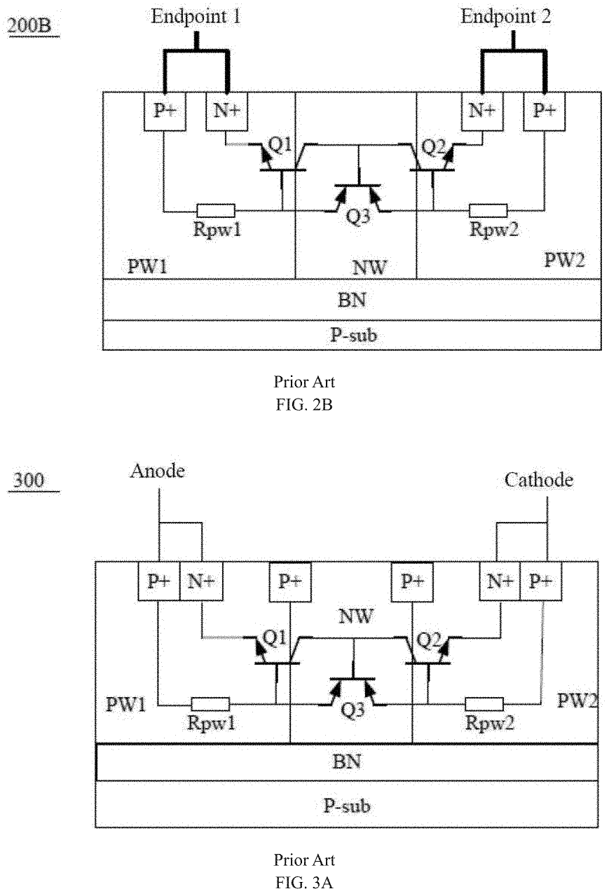

FIG. 2A is a schematic sectional view and an equivalent circuit diagram of a unidirectional SCR device in a conventional art. FIG. 2B is a schematic sectional view and an equivalent circuit diagram of a first bidirectional SCR device in the conventional art.

As shown in FIG. 2A, the unidirectional SCR device 200A is formed on a P-type semiconductor substrate P-sub, including an N-type buried layer BN formed on the P-type semiconductor substrate, and an N well (NW) and a P well (PW) located above the N-type buried layer BN. A P+ injection region and an N+ injection region are formed in the N well, and a P+ injection region and an N+ injection region are formed in the P well. The P+ injection region and the N+ injection region in the N well are used as an anode of the unidirectional SCR device 200A, and are connected to an anode terminal. The P+ injection region and the N+ injection region in the P well are used as a cathode of the unidirectional SCR device 200A, and are connected to a cathode terminal. The P+ injection region and the N+ injection region in the N well, the P+ injection region and the N+ injection region in the P well, the N well and the P well jointly form the unidirectional SCR device 200A. When an ESD pulse applied to the anode terminal breaks down a junction formed by the N well and the P well, an SCR loop is turned on, and an ESD current release path is formed.

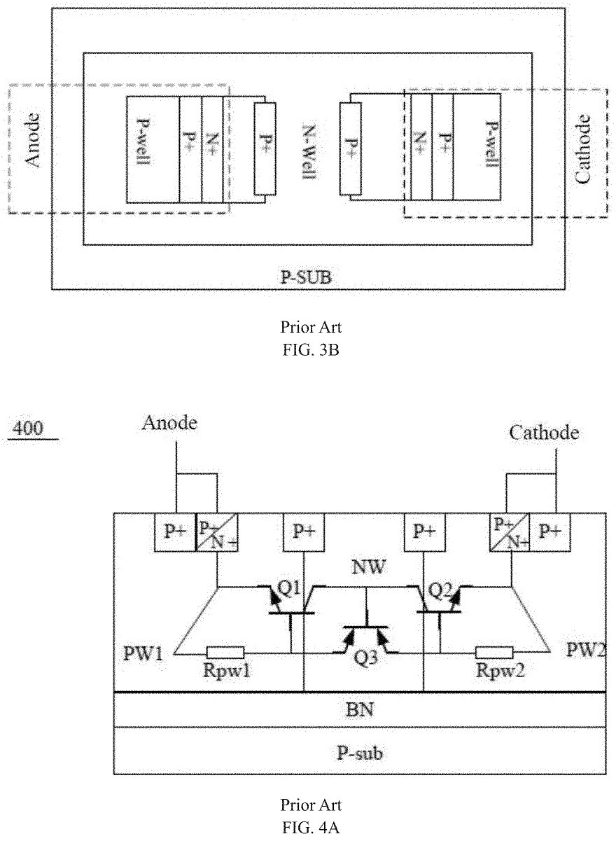

As shown in FIG. 2B, the bidirectional SCR device 200B is formed on a P-type semiconductor substrate P-sub, including an N-type buried layer BN formed on the P-type semiconductor substrate, a first P well (PW1) and a second P well (PW2) located above the N-type buried layer BN, and an N well (NW) located between the first P well and the second P well. A P+ injection region and an N+ injection region are formed in the first P well (PW1), and a P+ injection region and an N+ injection region are formed in the second P well (PW2). The P+ injection region and the N+ injection region in the first P well (PW1) are used as an anode and are connected to an anode terminal, and the P+ injection region and the N+ injection region in the second P well (PW2) are used as a cathode and are connected to a cathode terminal. Alternatively, the P+ injection region and the N+ injection region in the second P well (PW2) are used as an anode and are connected to an anode terminal, and the P+ injection region and the N+ injection region in the first P well (PW1) are used as cathode and are connected to a cathode terminal. The P+ injection region and the N+ injection region in the first P well (PW1), the P+ injection region and the N+ injection region in the second P well (PW2), the N well, the first P well (PW1) and the second P well (PW2) jointly form the bidirectional SCR device 200B. An operation principle of the bidirectional SCR device 200B in the case of unilateral conduction is the same as that of the unidirectional SCR device 200A. As shown in FIG. 2B, the bidirectional SCR device 200B is of a symmetric structure. When a positive ESD pulse appears at an endpoint 1, Q3 and Q2 form an SCR loop to discharge an ESD current. Similarly, when the positive ESD pulse appears at an endpoint 2, Q1 and Q3 are turned on to discharge the ESD current. The bidirectional SCR device can realize bidirectional protection. However, since the bidirectional SCR device is triggered by well breakdown and a trigger voltage is large, when the ESD pulse is lower than the trigger voltage, the ESD pulse cannot be discharged, which may cause failure of ESD protection failure and damages to the device. Therefore, the SCR device is required to be improved to reduce its trigger voltage. FIG. 3A is a schematic sectional view and an equivalent circuit diagram of a second bidirectional SCR device in the conventional art. FIG. 3B is a schematic top view of the bidirectional SCR device shown in FIG. 3A.

The bidirectional SCR device 300 shown in FIG. 3A and FIG. 3B is improved on the basis of the SCR device shown in FIG. 2B. P-type injection regions are added at junctions of the first P well, the second P well and the N well. In this way, the SCR device 300 is triggered by NW/P+ junction breakdown, which reduces the trigger voltage, but the sustaining voltage is still low. If a power supply voltage is greater than the sustaining voltage, a power supply may provide energy to maintain a latch-up, and the latch-up can be maintained until the energy of the power supply is depleted. In this way, the ESD protection device cannot be restored to a normally off state after the ESD pulse, resulting in failure.

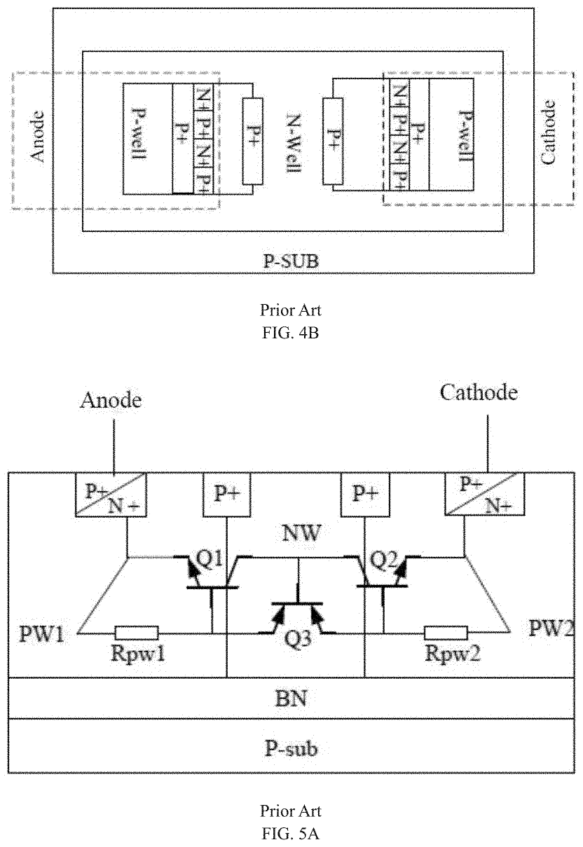

FIG. 4A is a schematic sectional view and an equivalent circuit diagram of a third bidirectional SCR device in the conventional art. FIG. 4B is a schematic top view of the bidirectional SCR device shown in FIG. 4A.

The bidirectional SCR device 400 shown in FIG. 4A and FIG. 4B is improved on the basis of the SCR device shown in FIG. 3A and FIG. 3B. N+ injection regions in the first P well and the second P well are replaced by an alternate structure of N+ and P+ island injection regions. N+ is replaced by an alternate structure of P+ and N+, and potentials connected to N+ and P+ are the same. Therefore, movement of carriers like PN junctions exists, a number of electrons emitted by an N+ structure and configured to turn on an NPN is reduced, and injection efficiency of an emitter junction is reduced. As the injection efficiency of the emitter junction is reduced, it is more difficult to turn on the NPN, and an ESD pulse with higher energy is required for the triggering. Since the latch-up is positive feedback formed by mutual promotion and turn-on of the NPN and a PNP, it is more difficult to trigger the NPN. Therefore, it is more difficult to form the latch-up. That is, the bidirectional SCR device 400 shown in FIG. 4A and FIG. 4B improves the sustaining voltage by reducing the injection efficiency of the emitter junction of the NPN to make it more difficult to enter a latch-up state after the NPN is triggered

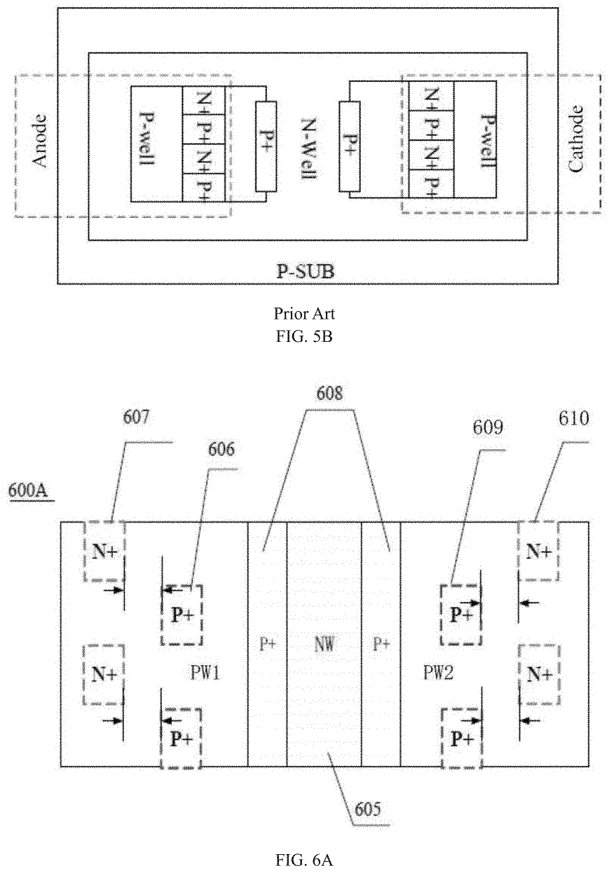

FIG. 5A is a schematic sectional view and an equivalent circuit diagram of a fourth bidirectional SCR device in the conventional art. FIG. 5B is a schematic top view of the bidirectional SCR device shown in FIG. 5A.

The bidirectional SCR device 500 shown in FIG. 5A and FIG. 5B is improved on the basis of the SCR device shown in FIG. 4A and FIG. 4B. The P+ injection regions in the first P well and the second P well are removed, and anode and cathode positions are directly replaced with the alternate structure of N+ and P+ island injection regions. Although the sustaining voltage is higher, it also has the problem of low ESD robustness.

Therefore, based on the shortcomings of the structure of the ESD device in the conventional art, the present disclosure provides a bidirectional ESD protection device that can not only increase the sustaining voltage but also improve the ESD robustness.

In one embodiment, a bidirectional ESD protection device is provided, the bidirectional ESD protection device including:

a first well region and a second well region having a first conductivity type and formed in the semiconductor substrate;

a third well region having a second conductivity type and formed in the semiconductor substrate, the third well region being located between the first well region and the second well region and located on a same straight line with the first well region and the second well region, the second conductivity type being opposite to the first conductivity type;

two or more first injection regions and two or more second injection regions formed in the first well region, and two or more fourth injection regions and two or more fifth injection regions formed in the second well region, the first injection regions and the fourth injection regions having the first conductivity type, the second injection regions and the fifth injection regions having the second conductivity type, the first injection regions being spaced along a length direction of the first well region, the second injection regions being spaced along the length direction of the first well region, the fourth injection regions being spaced along a length direction of the second well region, the fifth injection regions being spaced along the length direction of the second well region, the first injection regions and the second injection regions in the length direction of the first well region and the fourth injection regions and the fifth injection regions in the length direction of the second well region being respectively located on different straight lines and staggered from each other by a distance; and

third injection regions formed at a boundary of the first well region and the third well region and at a boundary of the second well region and the third well region, the third injection regions having the first conductivity type, the third injection regions extending along the length direction of the first well region;

wherein the first injection regions, the second injection regions, the third injection regions, the fourth injection regions, and the fifth injection regions constitute the bidirectional SCR device with the first well region, the second well region and the third well region, the first injection regions and the second injection regions in the first well region are used as a first electrode of the bidirectional SCR device, the fourth injection regions and the fifth injection regions in the second well region are used as a second electrode of the bidirectional SCR device, and the first electrode and the second electrode are an anode and a cathode of the bidirectional SCR device respectively.

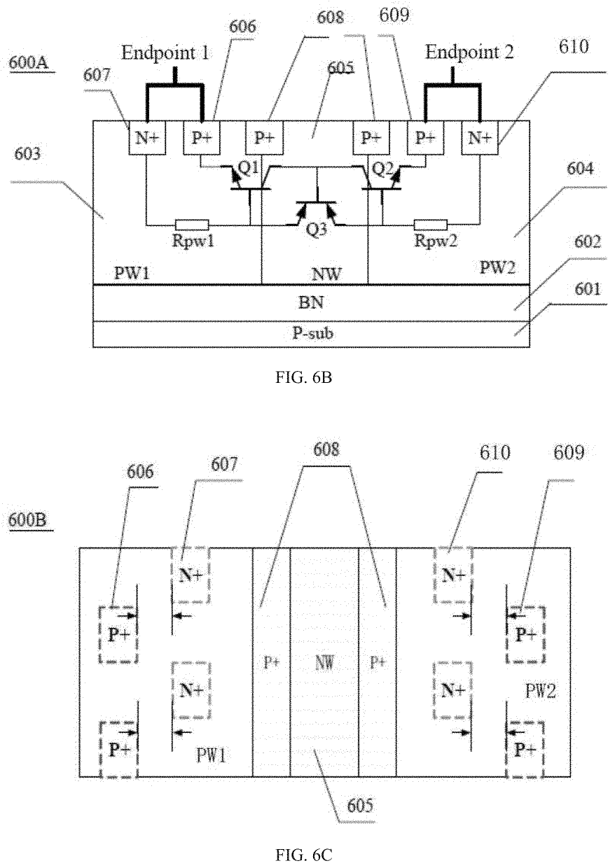

FIG. 6A is a schematic top view of a bidirectional ESD protection device according to an embodiment of the present disclosure. FIG. 6B is a schematic sectional view and an equivalent circuit diagram of the bidirectional ESD protection device shown in FIG. 6A.

As shown in FIG. 6A and FIG. 6B, in one embodiment, a bidirectional ESD protection device 600A is provided. The bidirectional ESD protection device 600A includes a bidirectional SCR device formed on a semiconductor substrate 601.

In one embodiment, the semiconductor substrate 601 may be made of at least one of the following materials: Si, Ge, SiGe, SiC, SiGeC, InAs, GaAs, InP or other III/V compound semiconductor materials, or may include a multilayer structure, a silicon on insulator (SOI), a stacked silicon on insulator (SSOI), a stacked silicon germanium on insulator (S-SIGEOI), a silicon germanium on insulator (SiGeOI), a germanium on insulator (GeOI), and the like composed of the above semiconductor materials. As an example, in this embodiment, the semiconductor substrate is made of monocrystalline silicon.

In one embodiment, the semiconductor substrate 601 has a first conductivity type. The first conductivity type is, for example, P-type. That is, the semiconductor substrate 601 is a P-type semiconductor substrate. It should be understood that, in other embodiments, the semiconductor substrate 601 has a second conductivity type. The second conductivity type is, for example, N-type. The semiconductor substrate 601 may also be an N-type semiconductor substrate.

In one embodiment, the bidirectional SCR device in the bidirectional ESD protection device 600A includes a buried layer 602 formed above the semiconductor substrate 601, a first well region 603, a second well region 604, a third well region 605, a first injection region 606, a second injection region 607, a third injection region 608, a fourth injection region 609 and a fifth injection region 610. The buried layer 602 and the third well region 605 have the second conductivity type, such as N type. The semiconductor substrate 601, the first well region 603 and the second well region 604 have the first conductivity type, such as P type. The second conductivity type is opposite to the first conductivity type.

The buried layer 602 is formed between the semiconductor substrate 601 and the first well region 603, the second well region 604, the third well region 605, and is configured to isolate the well regions above the buried layer 602 from the semiconductor substrate 601 below the buried layer 602.

In one embodiment, the buried layer 602 includes a deep N buried layer.

In one embodiment, the buried layer 602 may be formed by diffusion.

The first well region 603 and the second well region 604 are formed above the buried layer 602. The first well region 603 and the second well region 604 may be formed by injecting doped ions of the first conductivity type into the semiconductor substrate 601. An injection concentration and an injection depth of the doped ions in the first well region 603 and the second well region 604 may be determined according to a design requirement, which is not specifically limited herein.

The third well region 605 is located between the first well region 603 and the second well region 604, and is located on a same straight line with the first well region 603 and the second well region 604. The third well region 605 may be formed by injecting doped ions of the second conductivity type into the semiconductor substrate 601. An injection concentration and an injection depth of the doped ions in the third well region 605 may be determined according to a design requirement, which is not specifically limited herein.

The first injection region 606 and the second injection region 607 are formed in the first well region 603 and are used as a first electrode of the bidirectional SCR device. The fourth injection region 609 and the fifth injection region 610 are formed in the second well region 604 and are used as a second electrode of the bidirectional SCR device. The first electrode and the second electrode are an anode and a cathode of the bidirectional SCR device respectively. In this embodiment, two or more first injection regions 606 and two or more second injection regions 607 are formed in the first well region 603. The first injection regions 606 have the first conductivity type, such as P type, and the second injection regions 607 have the second conductivity type, such as N type. The first injection regions 606 are spaced along a length direction of the first well region 603, and the second injection regions 607 are spaced along the length direction of the first well region 603. Two or more fourth injection region 609 and two or more fifth injection regions 610 are formed in the second well region 604. The fourth injection regions 609 have the first conductivity type, such as P type, and the fifth injection regions 610 have the second conductivity type, such as N type. The fourth injection regions 609 are spaced along a length direction of the second well region 604, and the fifth injection regions 610 are spaced along the length direction of the second well region 604. That is, in this embodiment, the first injection regions 606, the second injection regions 607, the fourth injection regions 609 and the fifth injection regions 610 are no longer strip injection regions, but spaced island injection regions. Moreover, the first injection regions 606 and the second injection regions 607 in the length direction of the first well region 603 and the fourth injection regions 609 and the fifth injection regions 610 in the length direction of the second well region 604 are respectively located on different straight lines and staggered from each other by a distance. The first injection regions 606 and the second injection regions 607 are staggered from each other in a width direction of the first well region 603 and are not on a same straight line. The fourth injection regions 609 and the fifth injection regions 610 are staggered from each other in a width direction of the second well region 604 and are not on a same straight line. That is, in the SCR device of this embodiment, the island P+ injection regions and N+ injection regions are not on the same straight line, but are staggered from each other by a distance, thereby improving its ESD robustness.

The third injection regions 608 are formed at a boundary of the first well region 603 and the third well region 605 and at a boundary of the second well region 604 and the third well region 605 respectively. The third injection regions 608 have the first conductivity type, such as P type. The third injection regions 608 extend along the length direction of the first well region 603/second well region 604, having a length the same as that of the first well region 603/second well region 604. That is, the third injection regions 608 are strip injection regions or ribbon injection regions.

In one embodiment, the third injection regions 608 are formed in the first well region 603 and the second well region 604 respectively, and the third injection regions 608 adjoin the third well region 605.

In one embodiment, the third injection regions 608 are formed in the third well region 605, one of the third injection regions 608 adjoins the first well region 603, and the other of the third injection regions 608 adjoins the second well region 604.

In one embodiment, the third injection regions 608 span the first well region 603 and the third well region 605 and span the second well region 604 and the third well region 605 respectively (as shown in FIG. 6B).

In one embodiment, the first injection region 606, the fourth injection region 609 and the third injection region 608 are P+ injection regions formed by injecting P-type ions into the semiconductor substrate 601, a doping concentration of the P-type ions in the first injection region 606, the fourth injection region 609 and the third injection region 608 is higher than that in the first well region 603 and the second well region 604, and an injection depth of the P-type ions in the first injection region 606, the fourth injection region 609 and the third injection region 608 is less than depths of the first well region and the second well region. In one embodiment, the second injection region 607 and the fifth injection region 610 are N+ injection regions formed by injecting N-type ions into the semiconductor substrate 601, a doping concentration of the N-type ions in the second injection region 607 and the fifth injection region 610 is higher than that in the third well region, and an injection depth of the N-type ions in the second injection region 607 and the fifth injection region 610 is less than a depth of the third well region.

It is to be noted that, herein, length directions of the first well region 603 and the second well region 604 refer to a direction perpendicular to a paper surface in the sectional view shown in FIG. 6B or longitudinal directions in FIG. 6A and FIG. 6C, and width directions of the first well region 603 and the second well region 604 refer to transverse directions in FIG. 6A and FIG. 6C.

In addition, it is to be further noted that, although not shown, isolation structures may be formed between adjacent third injection regions 608, between the third injection regions 608 and the first injection regions 606, between the third injection regions 608 and the second injection regions 607, between the third injection regions 608 and the fourth injection regions 609, and between the third injection regions 608 and the fifth injection regions 610, so as to isolate the third injection regions 608 from each other and the third injection regions 608 from the first injection regions 606 or the second injection regions 607 or the fourth injection regions 609 or the fifth injection regions 610.

FIG. 6C is a schematic top view of another bidirectional ESD protection device according to an embodiment of the present disclosure. The bidirectional ESD protection device 600B shown in FIG. 6C is different from the bidirectional ESD protection device 600A shown in FIG. 6A and FIG. 6B as follows. In the bidirectional ESD protection device 600A shown in FIG. 6A and FIG. 6B, the first injection region 606 is closer to the third well region 605 than the second injection region 607, and the fourth injection region 609 is closer to the third well region 605 than the fifth injection region 610, while in the bidirectional ESD protection device 600B shown in FIG. 6C, the second injection region 607 is closer to the third well region 605 than the first injection region 606, and the fifth injection region 610 is closer to the third well region 605 than the fourth injection region 609.

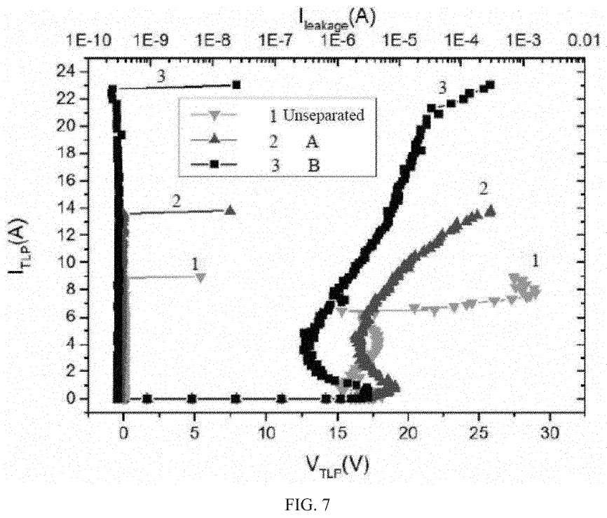

FIG. 7 is a diagram of TLP test results of the bidirectional ESD protection devices shown in FIG. 5A, FIG. 6A and FIG. 6C. In FIG. 7, curves 1, 2 and 3 represent the TLP test results of the bidirectional ESD protection devices shown in FIG. 5A, FIG. 6A and FIG. 6C respectively. As can be seen from FIG. 7, compared with the bidirectional ESD protection device shown in FIG. 5A, overcurrent capabilities of the bidirectional ESD protection devices shown in FIG. 6A and FIG. 6C are greatly improved (i.e., the ESD robustness is improved). The bidirectional ESD protection device shown in FIG. 6A has a higher sustaining voltage, while the bidirectional ESD protection device shown in FIG. 6B has a stronger overcurrent capability. This is due to the following reasons. Firstly, compared with the bidirectional ESD protection device shown in FIG. 5A, the bidirectional ESD protection device shown in FIG. 6A has a higher trigger voltage because an effective base of an NPN (NW/PW/N+) structure of an SCR path increases and it is more difficult to trigger the NPN, so it has a higher Vt1 (Vt1 is the trigger voltage). Moreover, since gain of the NPN decreases, the SCR path requires higher energy to maintain mutually promoting positive feedback, so Vh (Vh is the sustaining voltage) increases. It2 (current) of the bidirectional ESD protection device shown in FIG. 6A is higher because N+ and P+ in the bidirectional ESD protection device shown in FIG. 5A contact to lead to generation of a depletion region, and P+ and N+ have smaller conductive areas. In the bidirectional ESD protection device shown in FIG. 6A, N+ and P+ are separated, N+ and P+ have larger conductive areas, and current concentration is not as high as that of the bidirectional ESD protection device shown in FIG. 5A, so the current capability is stronger. Secondly, P+ ground of a cathode terminal of the bidirectional ESD protection device shown in FIG. 6C is farther from floating P+ on the right. Due to the existence of well resistance, a potential of the floating P+ on the right of the bidirectional ESD protection device shown in FIG. 6C is higher, and the emitter junction of the NPN has higher pressure drop, resulting in easier triggering of the NPN of the bidirectional ESD protection device shown in FIG. 6C. Therefore, the trigger voltage of the bidirectional ESD protection device shown in FIG. 6C is lower than that of the bidirectional ESD protection device shown in FIG. 6A. In the case of easier triggering, higher energy is not required to maintain positive feedback, and Vh is low. Therefore, the current capability of the bidirectional ESD protection device shown in FIG. 6C is strong. ESD releases energy, and there is a tradeoff between V and It2 (Power=Voltage X current). Assuming that two devices can withstand same ESD energy, the bidirectional ESD protection device shown in FIG. 6A has a stronger voltage after triggering than the bidirectional ESD protection device shown in FIG. 6C, so It2 may be smaller.

In the ESD protection device according to this embodiment, the first injection region and the second injection region used as the first electrode are set as a plurality of first injection regions arranged and spaced along the length direction of the first well region and a plurality of second injection regions arranged and spaced along the length direction of the first well region, the first injection regions and the second injection regions are located on different straight lines and are staggered from each other by a distance, and the first injection regions and the second injection regions are staggered from each other in the width direction of the first well region; the fourth injection region and the fifth injection region used as the second electrode are set as a plurality of fourth injection regions arranged and spaced along the length direction of the second well region and a plurality of fifth injection regions arranged and spaced along the length direction of the second well region, the fourth injection regions and the fifth injection regions are located on different straight lines and are staggered from each other by a distance, and the fourth injection regions and the fifth injection regions are staggered from each other in the width direction of the second well region. The first electrode and the second electrode are an anode and a cathode of the bidirectional SCR device. Thus, the bidirectional ESD protection device has a relatively high sustaining voltage, and greatly improved ESD robustness compared with the previous structure, which can improve the ESD robustness by more than one time.

In another aspect of the present disclosure, an electronic apparatus is further provided, including a bidirectional ESD protection device for IC chips and electronic components connected to the bidirectional ESD protection device. The bidirectional ESD protection device includes a bidirectional SCR device formed on a semiconductor substrate. The bidirectional ESD protection device includes: a first well region and a second well region having a first conductivity type and formed in the semiconductor substrate; a third well region having a second conductivity type and formed in the semiconductor substrate, the third well region being located between the first well region and the second well region and located on a same straight line with the first well region and the second well region, the second conductivity type being opposite to the first conductivity type; two or more first injection regions and two or more second injection regions formed in the first well region, the first injection regions having the first conductivity type, the second injection regions having the second conductivity type, the first injection regions being spaced along a length direction of the first well region, the second injection regions being spaced along the length direction of the first well region, the first injection regions and the second injection regions being located on different straight lines and staggered from each other by a distance, and two or more fourth injection regions and two or more fifth injection regions formed in the second well region. The fourth injection regions have the first conductivity type, such as P type, and the fifth injection regions have the second conductivity type, such as N type. The fourth injection regions are spaced along a length direction of the second well region, and the fifth injection regions are spaced along the length direction of the second well region. Third injection regions are formed at a boundary of the first well region and the third well region and at a boundary of the second well region and the third well region, the third injection regions having the first conductivity type, the third injection regions extending along the length direction of the first well region/second well region; wherein the first injection regions, the second injection regions, the third injection regions, the fourth injection regions, and the fifth injection regions constitute the bidirectional SCR device with the first well region, the second well region and the third well region, the first injection regions and the second injection regions in the first well region are used as a first electrode of the bidirectional SCR device, the fourth injection regions and the fifth injection regions in the second well region are used as a second electrode of the bidirectional SCR device, and the first electrode and the second electrode are an anode and a cathode of the bidirectional SCR device respectively.

The electronic components may be any electronic component such as a discrete device and an integrated circuit.

The electronic apparatus in this embodiment may be any electronic product or equipment such as a mobile phone, a tablet computer, a laptop computer, a netbook, a game console, a television set, a VCD, a DVD, a navigator, a camera, a video camera, a voice recorder, an MP3, an MP4, and a PSP, or any intermediate product including the semiconductor device.

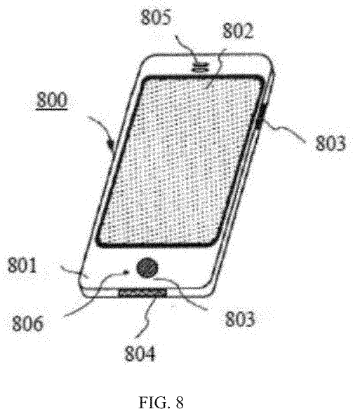

In one embodiment, the electronic apparatus includes a mobile phone. As shown in FIG. 8, a display portion 802 in a housing 801, an operation button 803, an external connection port 804, a speaker 805, a microphone 806 and so on are arranged outside the mobile phone 800.

With the electronic apparatus according to the embodiment of the present disclosure, since the included ESD protection device can improve the ESD robustness while increasing the sustaining voltage, the current discharge capability is improved, so as to achieve a better ESD protection effect. Therefore, the electronic apparatus also has similar advantages.

The present disclosure has been illustrated by the above embodiments, but it should be understood that the above embodiments are for exemplary and illustrative purposes only and are not intended to limit the present disclosure to the scope of the described embodiments. In addition, those skilled in the art can understand that the present disclosure is not limited to the above embodiments, and more variations and modifications can be made according to the teachings of the present disclosure, all of which fall within the scope of protection of the present disclosure. The scope of protection of the present disclosure is defined by the appended claims and equivalent scopes thereof.

1. A bidirectional Electro-Static Discharge (ESD) protection device, the bidirectional ESD protection device comprising a bidirectional Silicon Controlled Rectifier (SCR) device formed on a semiconductor substrate, the bidirectional ESD protection device comprising:
a first well region and a second well region having a first conductivity type and formed in the semiconductor substrate;
a third well region having a second conductivity type and formed in the semiconductor substrate, the third well region being located between the first well region and the second well region and located on a same straight line with the first well region and the second well region, the second conductivity type being opposite to the first conductivity type;
two or more first injection regions and two or more second injection regions formed in the first well region, and two or more fourth injection regions and two or more fifth injection regions formed in the second well region, the first injection regions and the fourth injection regions having the first conductivity type, the second injection regions and the fifth injection regions having the second conductivity type, the first injection regions being spaced along a length direction of the first well region, the second injection regions being spaced along the length direction of the first well region, the fourth injection regions being spaced along a length direction of the second well region, the fifth injection regions being spaced along the length direction of the second well region, the first injection regions and the second injection regions in the length direction of the first well region and the fourth injection regions and the fifth injection regions in the length direction of the second well region being respectively located on different straight lines and staggered from each other by a distance; and
third injection regions formed at a boundary of the first well region and the third well region and at a boundary of the second well region and the third well region, the third injection regions having the first conductivity type, the third injection regions extending along the length direction of the first well region;
wherein the first injection regions, the second injection regions, the third injection regions, the fourth injection regions, and the fifth injection regions constitute the bidirectional SCR device with the first well region, the second well region and the third well region, the first injection regions and the second injection regions in the first well region are used as a first electrode of the bidirectional SCR device, the fourth injection regions and the fifth injection regions in the second well region are used as a second electrode of the bidirectional SCR device, and the first electrode and the second electrode are an anode and a cathode of the bidirectional SCR device respectively.

2. The bidirectional ESD protection device according to claim 1, wherein the first injection regions are closer to the third well region than the second injection regions, and the fourth injection regions are closer to the third well region than the fifth injection regions.

3. The bidirectional ESD protection device according to claim 1, wherein the second injection regions are closer to the third well region than the first injection regions, and the fifth injection regions are closer to the third well region than the fourth injection regions.

4. The bidirectional ESD protection device according to claim 1, wherein the third injection regions are formed in the first well region and the second well region respectively, and the third injection regions adjoin the third well region.

5. The bidirectional ESD protection device according to claim 1, wherein the third injection regions are formed in the third well region, one of the third injection regions adjoins the first well region, and the other of the third injection regions adjoins the second well region.

6. The bidirectional ESD protection device according to claim 1, wherein the third injection regions span the first well region and the third well region and span the second well region and the third well region respectively.

7. The bidirectional ESD protection device according to claim 1, wherein the first injection regions and the second injection regions are staggered from each other in a width direction of the first well region and are not on a same straight line; and the fourth injection regions and the fifth injection regions are staggered from each other in a width direction of the second well region and are not on a same straight line.

8. The bidirectional ESD protection device according to claim 1, further comprising: a buried layer formed between the semiconductor substrate and the first well region, the second well region, the buried layer having the second conductivity type.

9. The bidirectional ESD protection device according to claim 1, wherein the first conductivity type is P-type, and the second conductivity type is N-type.

10. The bidirectional ESD protection device according to claim 1, wherein the first conductivity type is N-type, and the second conductivity type is P-type.

11. The bidirectional ESD protection device according to claim 8, wherein the buried layer comprises a deep N buried layer.

12. The bidirectional ESD protection device according to claim 1, wherein isolation structures are formed between adjacent third injection regions, between the third injection regions and the first injection regions, between the third injection regions and the second injection regions, between the third injection regions and the fourth injection regions, and between the third injection regions and the fifth injection regions.

13. An electronic apparatus, comprising the bidirectional ESD protection device according to claim 1 and electronic components connected to the bidirectional ESD protection device.

14. The electronic apparatus according to claim 13, comprising a mobile phone, a tablet computer, a laptop computer, a netbook, a game console, a television set, a VCD, a DVD, a navigator, a camera, a video camera, a voice recorder, an MP3, an MP4, and a PSP.

15. The electronic apparatus according to claim 13, wherein the electronic components comprise a discrete device and an integrated circuit.

16. The bidirectional ESD protection device according to claim 1, wherein the third injection region has a length the same as that of the first well region or the second well region.

17. The bidirectional ESD protection device according to claim 1, wherein the third injection regions are strip injection regions or ribbon injection regions.

18. The bidirectional ESD protection device according to claim 1, wherein the first injection regions, the second injection regions, the fourth injection regions and the fifth injection regions are spaced island injection regions.

19. The bidirectional ESD protection device according to claim 1, wherein the first injection region, the fourth injection region and the third injection region are P+ injection regions formed by injecting P-type ions into the semiconductor substrate; a doping concentration of the P-type ions in the first injection region, the fourth injection region and the third injection region is higher than that in the first well region and the second well region, and an injection depth of the P-type ions in the first injection region, the fourth injection region and the third injection region is less than depths of the first well region and the second well region; the second injection region and the fifth injection region are N+ injection regions formed by injecting N-type ions into the semiconductor substrate; a doping concentration of the N-type ions in the second injection region and the fifth injection region is higher than that in the third well region, and an injection depth of the N-type ions in the second injection region and the fifth injection region is less than a depth of the third well region.

20. The bidirectional ESD protection device according to claim 8, wherein the buried layer is further formed between the semiconductor substrate and the first well region.
